(19) United States
(12) Patent Application Publication
(10) Pub. No.: US 2007/0254398 A1
(43) Pub. Date: Nov. 1, 2007

(54) Method of manufacturing semiconductor device

(75) Inventors: Toshihiro Wakabayashi, Kawasaki (JP); Takao Setoyama, Kawasaki (JP); Yuji Asano, Kawasaki (JP); Akio Igarashi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/528,536

(22) Filed: Sep. 28, 2006

(30) Foreign Application Priority Data
Apr. 28, 2006 (JP) 2006-125999

(51) Int. Cl. H01L 21/425

(52) U.S. Cl. 438/59; 438/202; 438/514

(57) ABSTRACT

A method of manufacturing a high-speed operable and broadband operable semiconductor device where a light-receiving element section, a CMOS element and a bipolar transistor element having a double polysilicon structure are formed on one chip. By performing the same conductivity type ion implantation, the same conductivity type diffusion layers (examples thereof include N-type diffusion layers, an anode diffusion layer, P-type well diffusion layer and collector diffusion layer as P-type diffusion layers, a cathode diffusion layer and collector contact diffusion layer as N-type diffusion layers, a source/drain diffusion layer and base Poly-Si diffusion layer as N-type diffusion layers, and a source/drain diffusion layer and base Poly-Si diffusion layer as P-type diffusion layers) are simultaneously formed in two or more regions among a light-receiving element region, CMOS element region and bipolar transistor element region of a semiconductor substrate or of an epitaxial layer over the semiconductor substrate.

### CROSS-REFERENCE TO RELATED APPLICATIONS

This application is based upon and claims the benefits of priority from the prior Japanese Patent Application No. 2006-125999, filed Apr. 28, 2006, the entire contents of which are incorporated herein by reference.

### BACKGROUND OF THE INVENTION

1. Field of the Invention

The present invention relates to a method of manufacturing a semiconductor device and more particularly to a method of manufacturing a semiconductor device where a light-receiving element section, a CMOS element and a bipolar transistor element are formed on one chip.

2. Description of the Related Art

Conventionally, most of light-receiving elements are formed as single elements. Therefore, in order to process received signals, a light-receiving element section is used together with a signal processing element section. Alternatively, a light-receiving element section and a signal processing semiconductor device are integrated in the same package. Thus, the light-receiving element section is used as a hybrid integrated circuit.

Against this background, there is proposed a method where a light-receiving element section and a signal processing element section are formed on one chip. According to the above-described method, miniaturization of circuits is enabled. Examples of the light-receiving element section and the signal processing element section include a photodiode and a Complementary Metal-Oxide Semiconductor (CMOS) element or bipolar transistor (NPN type transistor (hereinafter, referred to as an “NPN-Tr”) and PNP type transistor (hereinafter, referred to as a “PNP-Tr”)) for processing signals from the photodiode (see, e.g., Japanese Unexamined Patent Publication No. 11-045988).

Further, in a circuit in which the light-receiving element section and the signal processing element section are integrated, the light-receiving element section is used for high-speed purposes. Therefore, also the signal processing element section must be operated in a high-speed and in a broadband. Examples of the elements constituting such a signal processing element section include a bipolar transistor. When using such a transistor, a vertical circuit capable of high-speed operation can be easily formed.

However, the bipolar transistor has the following problems. That is, a base layer and emitter layer of the bipolar transistor are not formed in a self-aligning manner. Therefore, a surface area of the transistor increases as well as parasitic capacitance thereof increases, and as a result, a high-speed operation and a broadband operation become difficult.

Therefore, in a current bipolar transistor, it is predominantly used a double polysilicon structure where an emitter electrode and a base electrode are made of a polysilicon (Poly-Si) film. When using this structure, resistance of a transistor can be reduced, and as a result, a high-speed operation and a broadband operation are enabled.

However, a structure of the bipolar transistor with the double polysilicon structure is complicated. Therefore, also a manufacturing process of a circuit in which a light-receiving element section, a CMOS element and a bipolar transistor element having the double polysilicon structure are integrated is complicated. As a result, many steps and much time are required for the manufacture.

### SUMMARY OF THE INVENTION

In view of the foregoing, it is an object of the present invention to provide a method of manufacturing a high-speed operable and broadband operable semiconductor device where a light-receiving element section, a CMOS element and a bipolar transistor element having a double polysilicon structure are formed on one chip.

To accomplish the above object, according to the present invention, there is provided a method of manufacturing a semiconductor device where a light-receiving element section, a CMOS element and a bipolar transistor element are formed on one chip. The manufacturing method comprises the step of: performing, by ion implantation, simultaneously forming diffusion layers in two or more regions among a light-receiving element region, CMOS element region and bipolar transistor element region of a semiconductor substrate or of an epitaxial layer over the semiconductor substrate.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a schematic cross sectional view of a semiconductor device where a light-receiving element section, a CMOS element and a bipolar transistor element having a double polysilicon structure are formed on one chip.

FIGS. 2 to 8 are schematic cross sectional views illustrating each step of a manufacturing method of a semiconductor device according to the present embodiment.

FIG. 9 is another schematic cross sectional view of FIG. 2 illustrating each step of a manufacturing method of a semiconductor device according to the present embodiment.

FIG. 10 is another schematic cross sectional view of FIG. 4 illustrating each step of a manufacturing method of a semiconductor device according to the present embodiment.

### DESCRIPTION OF THE PREFERRED EMBODIMENTS

Preferred embodiments of the present invention will be described in detail below with reference to the accompanying drawings.

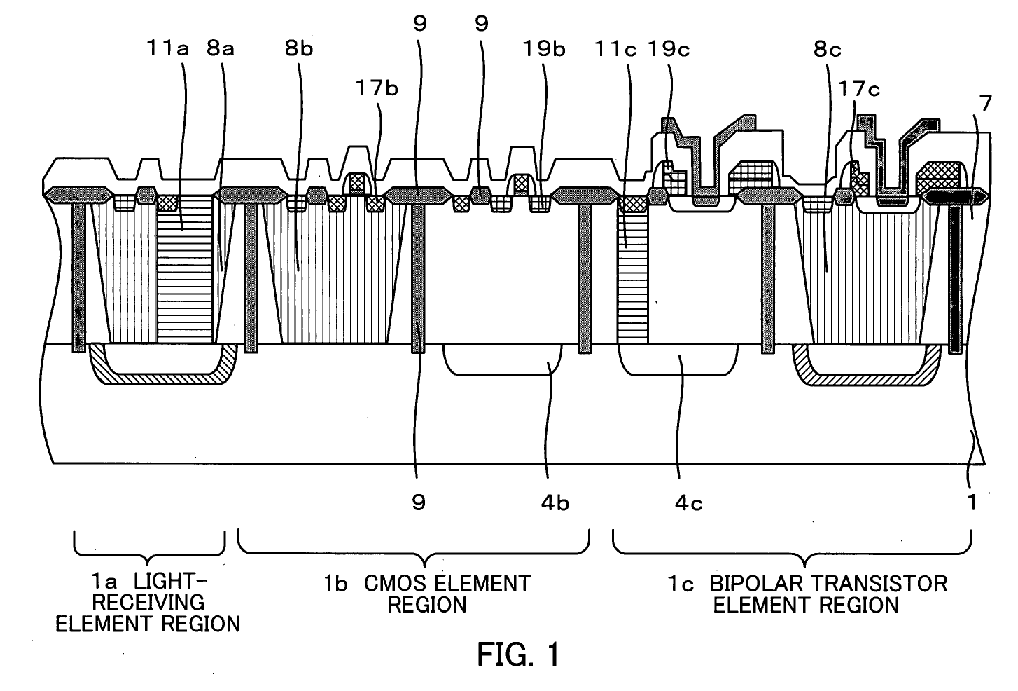

First, FIG. 1 will be simply described.

FIG. 1 is a schematic cross sectional view of a semiconductor device where a light-receiving element section, a CMOS element and a bipolar transistor element having a double polysilicon structure are formed on one chip.

An outline of a method of manufacturing the semiconductor device will be described below.

As shown in FIG. 1, a light-receiving element region 1a, a CMOS element region 1b and a bipolar transistor element region 1c are provided over a semiconductor substrate 1.

First, the same N-type ion implantation is performed to simultaneously form high-concentration N-type diffusion layers 4b and 4c in the CMOS element region 1b and bipolar transistor element region 1c of the semiconductor substrate 1.

Next, an epitaxial layer 7 is formed over the semiconductor substrate 1.

Next, the same P-type ion implantation is simultaneously performed to form an anode diffusion layer 8a, a P-type well diffusion layer 8b and a collector diffusion layer 8c in the light-receiving element region 1a, CMOS element region 1b and bipolar transistor element region 1c of the epitaxial layer 7, respectively. Thus, a low-concentration P-type diffusion layer is formed.

Next, an element isolation region 9 is formed in the epitaxial layer 7.

Next, the same N-type ion implantation is performed to form a cathode diffusion layer 11a and a collector contact diffusion layer 11c in the light-receiving element region 1a and bipolar transistor element region 1c of the epitaxial layer 7, respectively. Thus, a high-concentration N-type diffusion layer is formed.

Next, the same N-type ion implantation is performed to form a N-type source/drain diffusion layer 17b and a N-type base Poly-Si diffusion layer 17c in the CMOS element region 1b and bipolar transistor element region 1c of the epitaxial layer 7, respectively. Thus, a high-concentration N-type diffusion layer is formed.

Next, the same P-type ion implantation is performed to form a P-type source/drain diffusion layer 19b and a P-type base Poly-Si diffusion layer 19c in the CMOS element region 1b and bipolar transistor element region 1c of the epitaxial layer 7, respectively. Thus, a high-concentration P-type diffusion layer is formed.

As described above, according to the method of manufacturing a semiconductor device where the light-receiving element, the CMOS element and the bipolar transistor element having a double polysilicon structure are formed on one chip, the same conductivity-type ion implantation is performed. As a result, the high-concentration N-type diffusion layers 4b and 4c are simultaneously formed in the CMOS element region 1b and bipolar transistor element region 1c of the semiconductor substrate 1. Likewise, the same conductivity-type ion implantation is performed also in the regions of the epitaxial layer 7. As a result, the following diffusion layers can be simultaneously formed respectively. That is, the p-type anode diffusion layer 8a in the light-receiving element region la, the P-type well diffusion layer 8b in the CMOS element region 1b and the P-type collector diffusion layer 8c in the bipolar transistor element region 1c can be simultaneously formed. The n-type cathode diffusion layer 11a in the light-receiving element region 1a and the n-type collector contact diffusion layer 11c in the bipolar transistor element region 1c can be simultaneously formed. The N-type source/drain diffusion layer 17b in the CMOS element region 1b and the N-type base Poly-Si diffusion layer 17c in the bipolar transistor element region 1c can be simultaneously formed. The P-type source/drain diffusion layer 19b in the CMOS element region 1b and the P-type base Poly-Si diffusion layer 19c in the bipolar transistor element region 1c can be simultaneously formed. Therefore, the number of manufacturing steps of the semiconductor device can be reduced. This makes it possible to shorten the manufacturing time of the semiconductor device as well as to contribute to cost reduction.

Preferred embodiments will be described below.

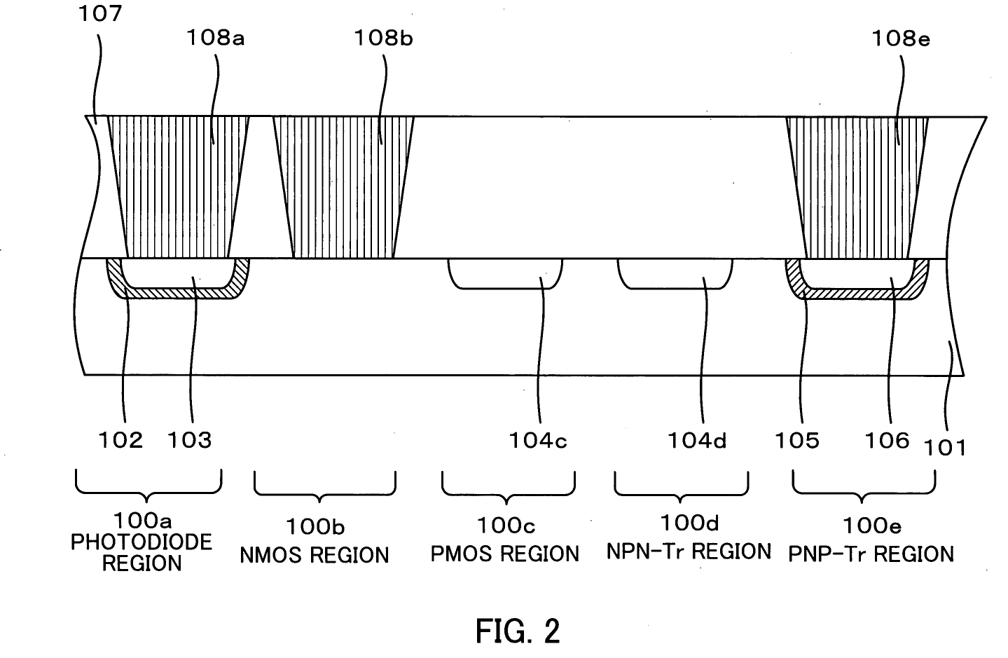

FIGS. 2 to 8 are schematic cross sectional views illustrating each step of the manufacturing method of a semiconductor device according to the present embodiment.

First, a photodiode region 100a, an NMOS region 100b, a PMOS region 100c, an NPN-Tr region 100d and a PNP-Tr region 100e are provided on a P-type semiconductor substrate 101 having resistivity of about 1 to 50 Ω·cm.

In the photodiode region 100a, the N-type ion implantation and the P-type ion implantation are performed to form a deep photodiode isolation N-type diffusion layer 102 and a relatively shallow first photodiode anode P-type diffusion layer 103 on the layer 102. In the PMOS region 100c and the NPN-Tr region 100d, the same N-type ion implantation is performed to form high-concentration N-type diffusion layers 104c and 104d (the ion implantation is performed such that an impurity concentration in the high-concentration N-type diffusion layers 104c and 104d is about 1×10¹⁸ to 1×10² cm⁻³). Also in the PNP-Tr region 100e, the N-type ion implantation and the P-type ion implantation are performed to form a deep PNP-Tr isolation N-type diffusion layer 105 and a relatively shallow PNP-Tr isolation P-type diffusion layer 106 on the layer 105 (the ion implantation is performed such that an impurity concentration in the PNP-Tr isolation P-type diffusion layer 106 is about 1×10¹⁷ to 1×10¹⁹ cm⁻³).

Next, a low-concentration N-type epitaxial layer 107 having resistivity of about 0.5 to 5 Ω·cm is formed on the P-type semiconductor substrate 101. In the photodiode region 100a, NMOS region 100b and PNP-Tr region 100e of the low-concentration N-type epitaxial layer 107, the same P-type ion implantation (e.g., boron (B) ion implantation at the dose amount of about 5×10¹¹ to 1×10¹⁴ cm⁻²) is performed to form a second photodiode anode P-type diffusion layer 108a, a P-type well diffusion layer 108b and a collector diffusion layer 108e, respectively (for the above steps, see FIG. 2).

At this time, any one of the P-type well diffusion layer 108b and the collector diffusion layer 108e, and the second photodiode anode P-type diffusion layer 108a may be simultaneously formed.

Next, a Local Oxidation Of Silicon (LOCOS) region 109 and a dielectric element isolation region 110 are formed on and within the low-concentration N-type epitaxial layer 107.

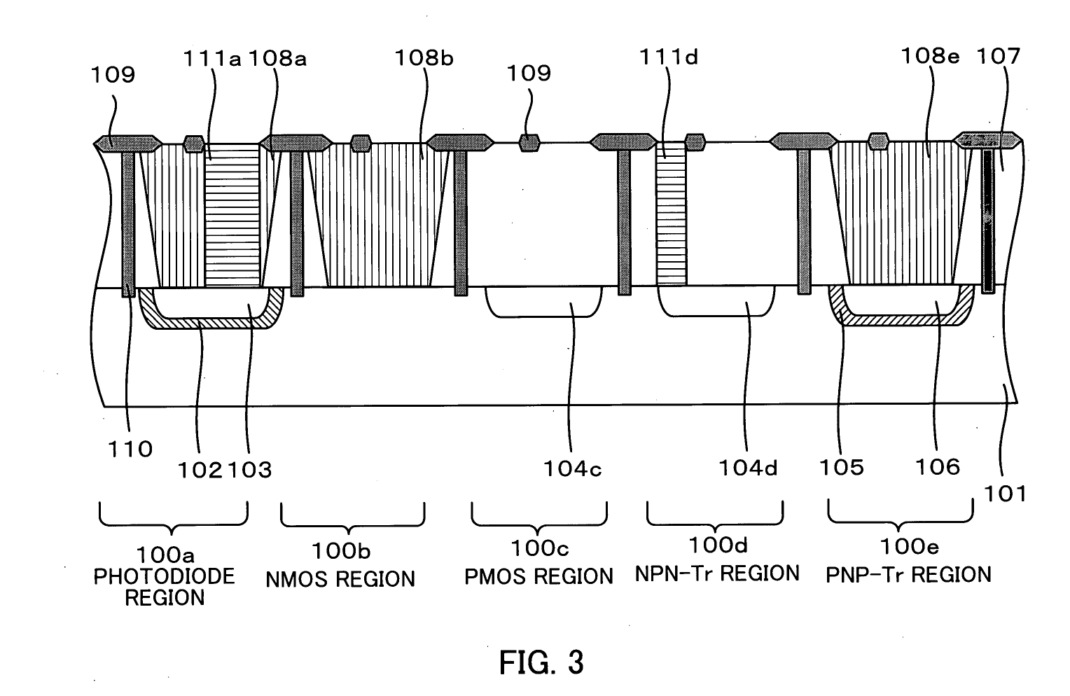

Next, in the photodiode region 100a and the NPN-Tr region 100d, the same N-type ion implantation (e.g., phosphorus (P) ion implantation at the dose amount of about 1×10¹⁴ to 1×10¹⁶ cm⁻²) is performed to form a cathode diffusion layer 111a and a collector contact diffusion layer 111d (for the above steps, see FIG. 3).

Next, on the low-concentration N-type epitaxial layer 107, an insulator such as a gate oxide film is formed, for example, by thermal oxidation.

Next, insulator in a base/emitter formation region of the NPN-Tr region 100d and the PNP-Tr region 100e is removed to allow insulator 112 to remain.

Next, on the whole surface of the low-concentration N-type epitaxial layer 107 having formed thereon the insulator 112, a non-doped Si layer 113 is formed, for example, using a Low-Pressure Chemical Vapor Deposition (LPCVD) method.

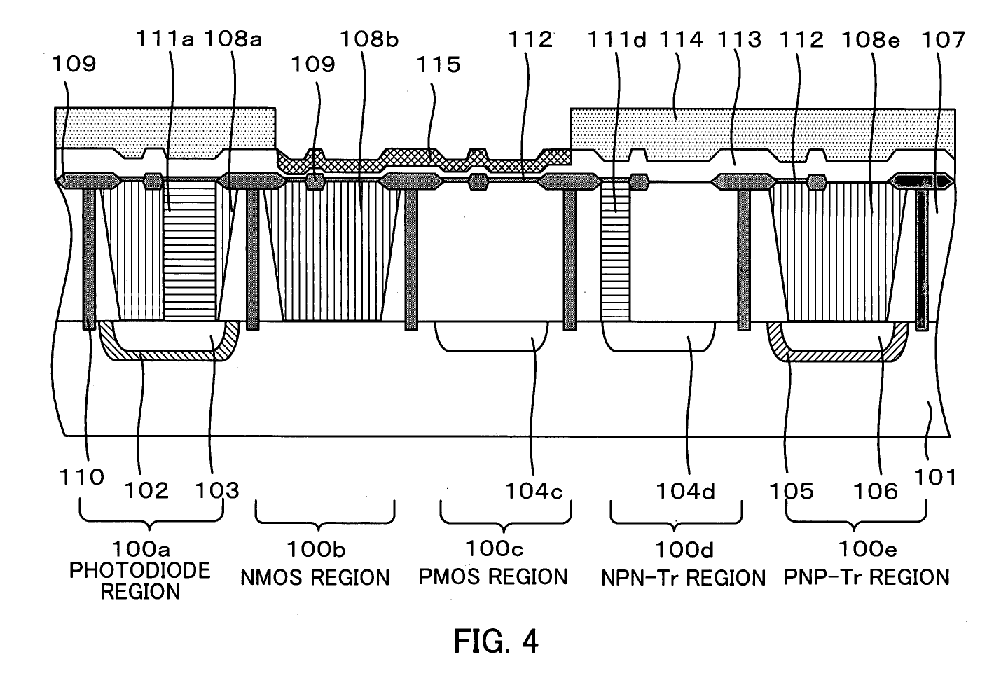

Next, the photolithography process is performed to form a photoresist mask 114. Using the mask 114, the N-type ion implantation (e.g., phosphorus (P) ion implantation at the dose amount of about 5×10¹⁴ to 5×10¹⁶ cm⁻²) is performed to form a Poly-Si diffusion layer 115 in the NMOS region 100b and the PMOS region 100c (for the above steps, see FIG. 4).

Next, after removal of the photoresist mask 114, each of the non-doped Si layer 113 and Poly-Si diffusion layer 115 in the NMOS region 100b and the PMOS region 100c is etched to form gate sections (a gate and sidewalls) 115b and 115c. At this time, non-doped Si layers 113d and 113e are formed in the NPN-Tr region 100d and the PNP-Tr region 100e, respectively. Further, the other non-doped Si layer 113 and Poly-Si diffusion layer 115 are removed. When the gate sections 115b and 115c in the NMOS region 100b and the PMOS region 100c are formed to have an LDD structure, an LDD diffusion layer may be formed by performing ion implantation before formation of the sidewalls.

Next, the photolithography process is performed to open the photoresist in respective predetermined regions where a cathode contact compensation diffusion layer 117a in the photodiode region 100a, a source/drain diffusion layer 117b in the NMOS region 100b, a back gate contact diffusion layer 117c in the PMOS region 100c, a collector contact compensation diffusion layer 117d in the NPN-Tr region 100d and a base Poly-Si diffusion layer 117e in the PNP-Tr region 100e are to be formed. Thus, a photoresist mask 116 is formed.

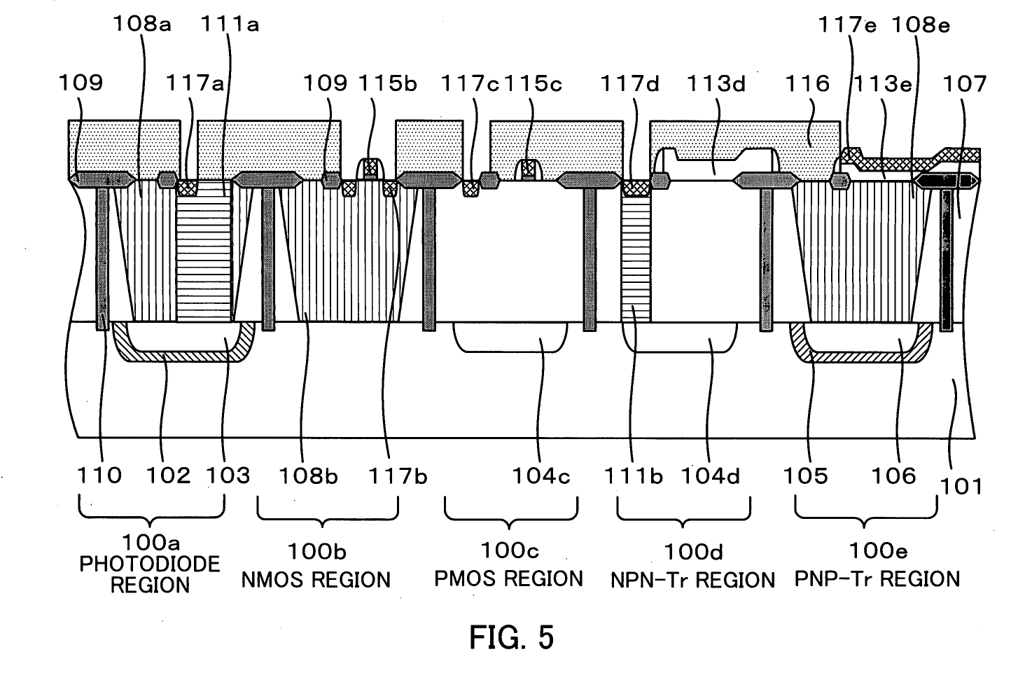

Next, using the formed photoresist mask 116, the same N-type ion implantation (e.g., arsenic (As) ion implantation at the dose amount of about 5×10¹⁴ to 5×10¹⁶ cm⁻²) is performed to form the cathode contact compensation diffusion layer 117a in the photodiode region 100a, the source/drain diffusion layer 117b in the NMOS region 100b, the back gate contact diffusion layer 117c in the PMOS region 100c, the collector contact compensation diffusion layer 117d in the NPN-Tr region 100d and the base Poly-Si diffusion layer 117e in the PNP-Tr region 100e. Impurities in the base Poly-Si diffusion layer 117e easily diffuse into the non-doped Si layer 113e by the subsequent heat treatment (for the above steps, see FIG. 5).

Next, after removal of the photoresist mask 116, another photolithography process is performed to open the photoresist in respective predetermined regions where an anode contact compensation diffusion layer 119a in the photodiode region 100a, a back gate contact diffusion layer 119b in the NMOS region 100b, a source/drain diffusion layer 119c in the PMOS region 100c, a base Poly-Si diffusion layer 119d in the NPN-Tr region 100d and a collector contact compensation diffusion layer 119e in the PNP-Tr region 100e are to be formed. Thus, a photoresist mask 118 is formed.

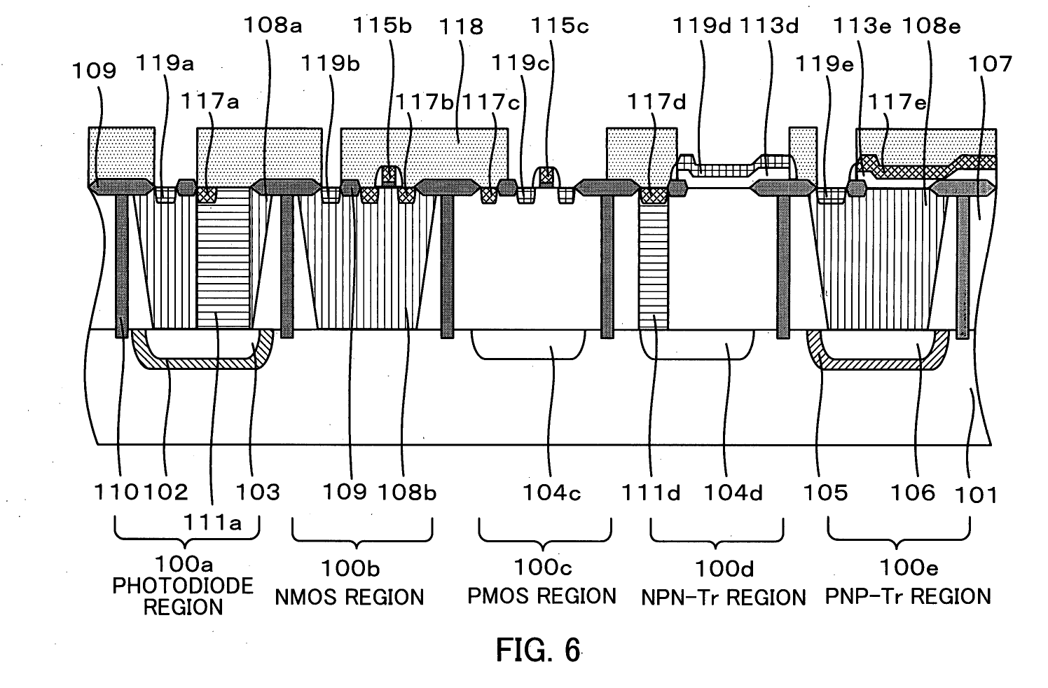

Next, using the formed photoresist mask 118, the same P-type ion implantation (e.g., boron (B) ion implantation at the dose amount of about 5×10¹⁴ to 5×10¹⁶ cm⁻²) is performed to form the anode contact compensation diffusion layer 119a in the photodiode region 100a, the back gate contact diffusion layer 119b in the NMOS region 100b, the source/drain diffusion layer 119c in the PMOS region 100c, the base Poly-Si diffusion layer 119d in the NPN-Tr region 100d and the collector contact compensation diffusion layer 119e in the PNP-Tr region 100e. Impurities in the Poly-Si diffusion layer 119d easily diffuse into the non-doped Si layer 113d by the subsequent heat treatment (for the above steps, see FIG. 6).

Next, after removal of the photoresist mask 118, a High-Temperature Oxidation film (HTO) 120 is formed on the whole surface.

Next, the base Poly-Si diffusion layers 119d and 117e in the base/emitter formation region as well as the HTO film 120 in the base/emitter formation region are opened in the NPN-Tr region 100d and the PNP-Tr region 100e.

Next, the P-type or N-type ion implantation is performed in each opening region to form bases 121d and 121e. Further, sidewall films 123d and 123e are formed.

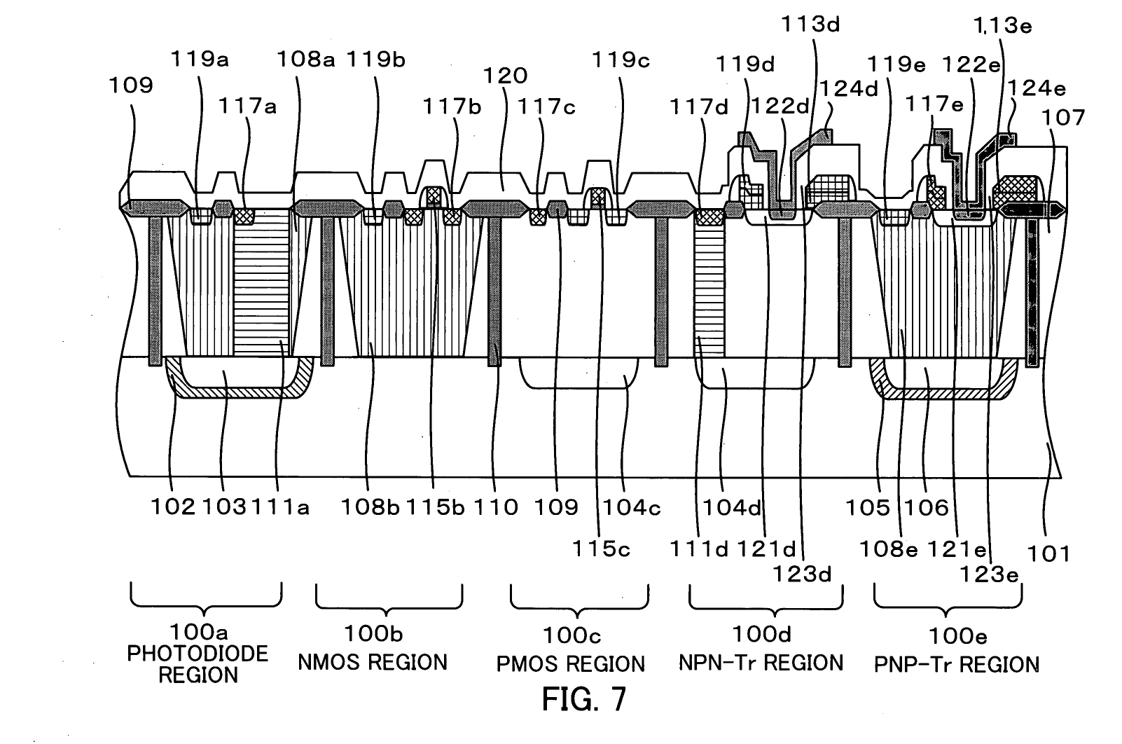

Next, the non-doped Poly-Si layer is formed on the whole surface including the opening regions. Further, the Poly-Si layer is etched to form emitter Poly-Si regions 124d and 124e. Thereafter, the N-type or P-type ion implantation is performed to dope impurities into the emitter Poly-Si regions 124d and 124e. Herein, a Poly-Si layer previously doped with impurities may be used in place of doping impurities into the emitter Poly-Si regions 124d and 124e. Through the subsequent heat treatment, doped impurities are allowed to diffuse from the emitter Poly-Si regions 124d and 124e to form emitters 122d and 122e (for the above steps, see FIG. 7).

Next, insulator 125 such as a silicon dioxide film (SiO₂) is formed on the whole surface, for example, by a High Density Plasma (HDP) method. The insulator 125 is flattened, for example, using a Chemical Mechanical Polishing (CMP) method, if necessary.

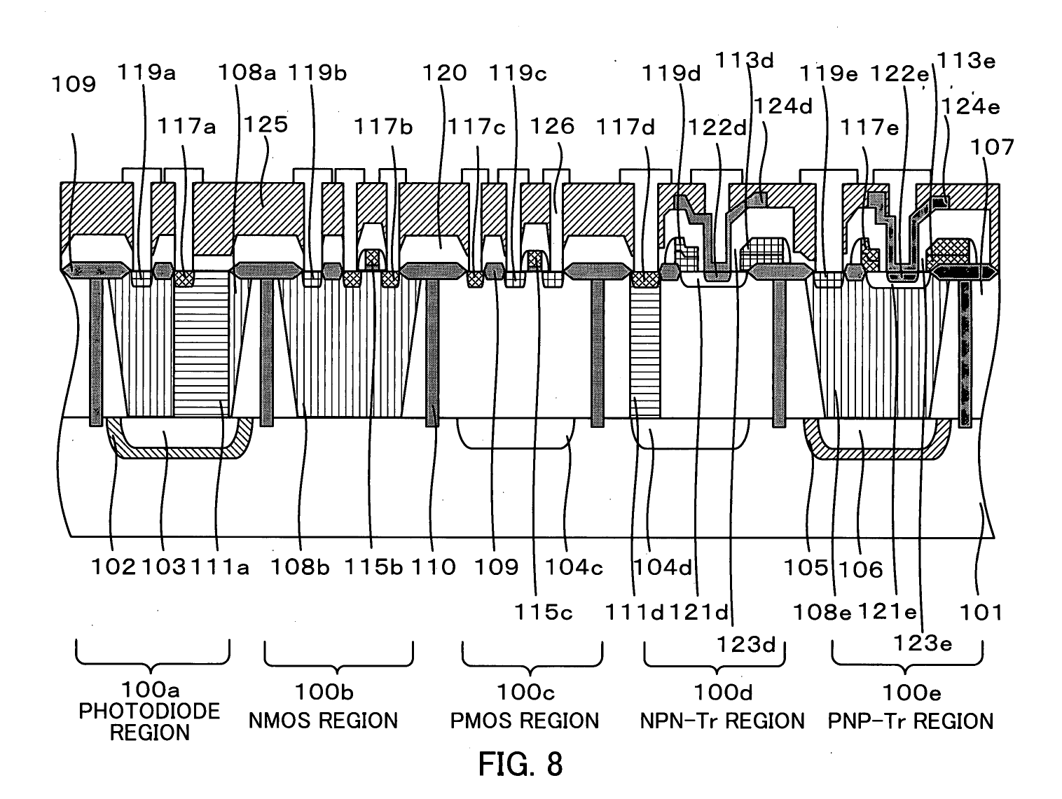

Next, in each of the photodiode region 100a, the NMOS region 100b, the PMOS region 100c, the NPN-Tr region 100d and the PNP-Tr region 100e, the insulator 125 for each terminal is opened to form a metallic wiring 126. A metallic wiring layer and an insulator layer are formed in the required number of layers (for the above steps, see FIG. 8).

Finally, after a metallic wiring process, a protective film such as a silicon nitride (SiN) film (not shown) is formed, for example, using a plasma CVD method.

As shown in FIG. 3, the LOCOS region 109 and the dielectric element isolation region 110 are formed on and within the low-concentration N-type epitaxial layer 107. In place of the LOCOS region 109 and the dielectric element isolation region 110, a PN junction isolation region can also be formed.

Formation of the PN junction isolation region will be described below.

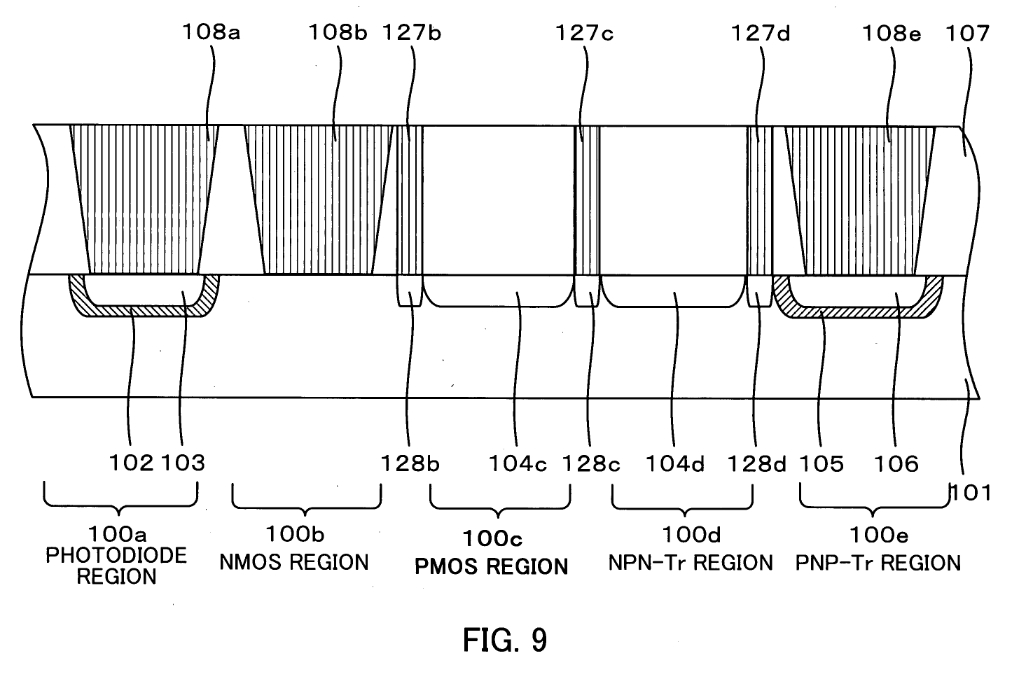

FIG. 9 is another schematic cross sectional view of FIG. 2 illustrating each step of the manufacturing method of a semiconductor device according to the present embodiment.

As shown in FIG. 2, in the photodiode region 100a, the N-type implantation and the P-type ion implantation are performed to form the deep photodiode isolation N-type diffusion layer 102 and the relatively shallow first photodiode anode P-type diffusion layer 103 on the layer 102. In the PMOS region 100c and the NPN-Tr region 100d, the N-type ion implantation is performed to form the high-concentration N-type diffusion layers 104c and 104d. In the PNP-Tr region 100e, the N-type ion implantation and the P-type ion implantation are performed to form the deep PNP-Tr isolation N-type diffusion layer 105 and the relatively shallow PNP-Tr isolation P-type diffusion layer 106 on the layer 105.

Further, the P-type ion implantation is performed to form high-concentration P-type diffusion layers 128b, 128c and 128d in the NMOS region 100b, PMOS region 100c and NPN-Tr region 100d of the P-type semiconductor substrate 101, as shown in FIG. 9.

Next, as shown in FIG. 2, the low-concentration N-type epitaxial layer 107 is formed on the P-type semiconductor substrate 101. In the photodiode region 100a, NMOS region 100b and PNP-Tr region 100e of the low-concentration N-type epitaxial layer 107, the P-type ion implantation is simultaneously performed to form the second photodiode anode P-type diffusion layer 108a, the P-type well diffusion layer 108b and the collector diffusion layer 108e. The subsequent steps are performed in the same manner as in the present embodiment.

Further, the P-type ion implantation is performed to form high-concentration P-type diffusion layers 127b, 127c and 127d in the NMOS region 100b, PMOS region 100c and NPN-Tr region 100d of the epitaxial layer 107, as shown in FIG. 9.

As described above, when the PN junction isolation region is formed in place of the LOCOS region 109 and the dielectric element isolation region 110, the respective regions of the photodiode region 100a, the NMOS region 100b, the PMOS region 100c, the NPN-Tr region 100d and the PNP-Tr region 100e can be electrically isolated.

On the other hand, the N-type ion implantation is simultaneously performed to form the cathode contact compensation diffusion layer 117a, the source/drain diffusion layer 117b, the back gate contact diffusion layer 117c, the collector contact compensation diffusion layer 117d and the base Poly-Si diffusion layer 117e in the opening regions of the photodiode region 100a, NMOS region 100b, PMOS region 100c, NPN-Tr region 100d and PNP-Tr region 100e of the photoresist mask 116, as shown in FIG. 5. Formation of the base Poly-Si diffusion layer 117e in the PNP-Tr region 100e may be performed using the following method.

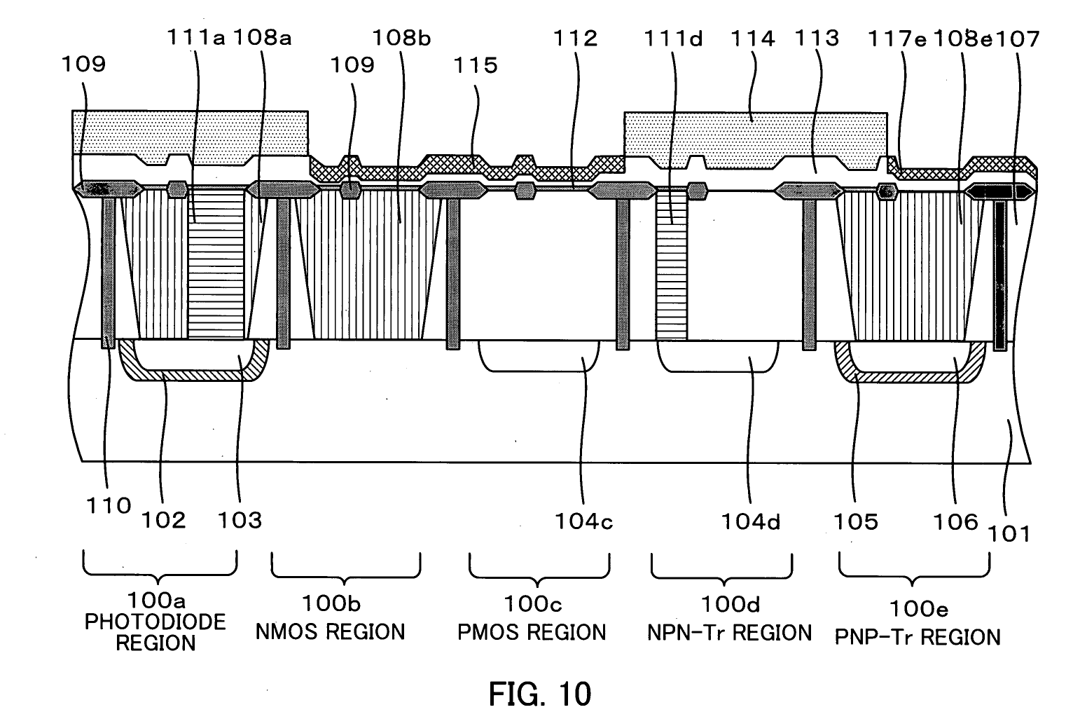

FIG. 10 is another schematic cross sectional view of FIG. 4 illustrating each step of the manufacturing method of a semiconductor device according to the present embodiment. Using the photoresist mask 114 formed through the photolithography process, the N-type ion implantation is performed to form the Poly-Si diffusion layer 115 in the NMOS region 100b and the PMOS region 100c, as shown in FIG. 4. At this time, the photolithography process is performed to open the photoresist in the predetermined region where a base Poly-Si diffusion layer 117e in the PNP-Tr region 100e is to be formed, as well as in the predetermined region where the Poly-Si diffusion layer 115 in the regions 100b and 100c is to be formed, as shown in FIG. 10. Thereafter, the N-type ion implantation is performed using the formed photoresist. As a result, the Poly-Si diffusion layer 115 in the NMOS region 100b and the PMOS region 100c as well as the base Poly-Si diffusion layer 117e in the PNP-Tr region 100e can be simultaneously formed. The subsequent steps are performed in the same manner as in the present embodiment.

As described above, according to the present embodiment, the N-type ion implantation is performed in the PMOS region 100c and NPN-Tr region 100d of the P-type semiconductor substrate 101. As a result, the high-concentration N-type diffusion layers 104c and 104d can be simultaneously formed. Further, the same conductivity type ion implantation is performed also in the regions of the low-concentration N-type epitaxial layer 107. As a result, the following diffusion layers can be simultaneously formed respectively. That is, the second photodiode anode P-type diffusion layer 108a in the photodiode region 100a, the P-type well diffusion layer 108b in the NMOS region 100b and the P-type collector diffusion layer 108e in the PNP-Tr region 100e can be simultaneously formed. The N-type cathode diffusion layer 111a in the photodiode region 100a and the N-type collector contact diffusion layer 111d in the NPN-Tr region 100d can be simultaneously formed. The N-type source/drain diffusion layer 117b in the NMOS region 100b and the N-type base Poly-Si diffusion layer 117e in the PNP-Tr region 100e can be simultaneously formed. The P-type source/drain diffusion layer 119c in the PMOS region 100c and the P-type base Poly-Si diffusion layer 119d in the NPN-Tr region 100d can be simultaneously formed. Therefore, the number of manufacturing steps of the semiconductor device can be reduced. This makes it possible to shorten the manufacturing time of the semiconductor device as well as to contribute to cost reduction.

The above-described formation conditions are just examples. Materials for film formation and a film formation method as well as ion species for diffusion layer formation can be suitably changed by using a known conventional technology. In the present embodiment, there is described a case where the P-type or N-type diffusion layer is formed on the P-type semiconductor substrate and on the low-concentration N-type epitaxial layer. Even in a case where the N-type diffusion layer or P-type diffusion layer is formed on the N-type semiconductor substrate and on the low-concentration P-type epitaxial layer, the same effect can be obtained.

In the present invention, the same conductivity type ion implantation is performed. As a result, the same conductivity type diffusion layers (examples thereof include the N-type diffusion layers 4b and 4c, the anode diffusion layer 8a, P-type well diffusion layer 8b and collector diffusion layer 8c as the P-type diffusion layers, the cathode diffusion layer 11a and collector contact diffusion layer 11c as the N-type diffusion layers, the source/drain diffusion layer 17b and base Poly-Si diffusion layer 17c as the N-type diffusion layers, and the source/drain diffusion layer 19b and base Poly-Si diffusion layer 19c as the P-type diffusion layers) can be simultaneously formed in two or more regions among the light-receiving element region 1a, CMOS element region 1b and bipolar transistor element region 1c of the semiconductor substrate 1 or of the epitaxial layer 7 over the semiconductor substrate 1. Therefore, the number of manufacturing steps of the semiconductor device can be reduced. This makes it possible to shorten the manufacturing time of the semiconductor device as well as to contribute to cost reduction.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method of manufacturing a semiconductor device where a light-receiving element section, a CMOS element and a bipolar transistor element are formed on one chip, comprising the step of
performing, by ion implantation, simultaneously forming diffusion layers in two or more regions among a light-receiving element region, CMOS element region and bipolar transistor element region of a semiconductor substrate or of an epitaxial layer over the semiconductor substrate.

2. The method according to claim 1, wherein the light-receiving element section has a photodiode.

3. The method according to claim 1, wherein the ion implantation forms an anode diffusion layer in the light-receiving element region of the epitaxial layer and simultaneously forms at least one of a well diffusion layer in the CMOS element region and a collector diffusion layer in the bipolar transistor element region of the epitaxial layer.

4. The method according to claim 3, wherein the ion implantation is performed by setting an ion species to a boron ion, and by setting the dose amount of the boron ion to about 5×10¹¹ to 1×10¹⁴ cm⁻².

5. The method according to claim 1, wherein the ion implantation forms a cathode diffusion layer and collector contact diffusion layer in the light-receiving element region and bipolar transistor element region of the epitaxial layer, respectively.

6. The method according to claim 5, wherein the ion implantation is performed by setting an ion species to a phosphorus ion, and by setting the dose amount of the phosphorus ion to about 1×10¹⁴ to 1×10¹⁶ cm⁻².

7. The semiconductor device according to claim 1, wherein the ion implantation forms a source/drain diffusion layer and polysilicon diffusion layer in the CMOS element region and bipolar transistor element region of the epitaxial layer, respectively.

8. The method according to claim 7, wherein the ion implantation is performed by setting an ion species to an arsenic ion, and by setting the dose amount of the arsenic ion to about 5×10¹⁴ to 5×10¹⁶ cm⁻².

9. The method according to claim 7, wherein the ion implantation is performed by setting an ion species to a boron ion, and by setting the dose amount of the boron ion to about 5×10¹⁴ to 5×10¹⁶ cm⁻².

10. The semiconductor device according to claim 1, wherein the ion implantation forms a source/drain diffusion layer and polysilicon diffusion layer in the CMOS element region and bipolar transistor element region of the epitaxial layer, respectively.

11. The method according to claim 10, wherein the ion implantation is performed by setting an ion species to a phosphorus ion, and by setting the dose amount of the phosphorus ion to about 5×10¹⁴ to 5×10¹⁶ cm⁻².

12. The method according to claim 1, wherein the semiconductor substrate is a P-type semiconductor substrate, and the epitaxial layer is an N-type epitaxial layer.

13. The method according to claim 1, wherein the semiconductor substrate is an N-type semiconductor substrate, and the epitaxial layer is a P-type epitaxial layer.

14. The method according to claim 1, further comprising the step of forming a PN junction isolation region as an element isolation region.
